(19) United States
(12) Patent Application Publication
(10) Pub. No.: US 2009/0279352 A1
(43) Pub. Date: Nov. 12, 2009

(54) Storage nodes, phase change memories including a doped phase change layer, and methods of operating and fabricating the same

(76) Inventors: Jin-seo Noh, Yongin-si (KR); Ki-jun Kim, Yongin-si (KR); Yoon-ho Khang, Yongin-si (KR); Woong-chul Shin, Yongin-si (KR); Dong-seok Suh, Yongin-si (KR)

Correspondence Address: HARNESS, DICKEY & PIERCE, P.L.C., P.O. BOX 8910, RESTON, VA, 20195, US

(21) Appl. No.: 12/458,700

(22) Filed: Jul. 21, 2009

Related U.S. Application Data
(62) Division of application No. 11/822,319, filed on Jul. 5, 2007.

(30) Foreign Application Priority Data
Jul. 4, 2006 (KR) 10-2006-0062409

(51) Int. Cl. G11C 11/00

(52) U.S. Cl. 365/163; 365/148

(57) ABSTRACT

Example embodiments may provide a doped phase change layer and a method of operating and fabricating a phase change memory with the example embodiment doped phase change layer. The phase change memory may include a storage node having a phase change layer and a switching device, wherein the phase change layer includes indium with a concentration ranging from about 5 at % to about 15 at %. The phase change layer may be a GST layer that includes indium. The phase change layer may be a GST layer that includes gallium.

### CROSS REFERENCE TO RELATED APPLICATION

This Divisional application claims the benefit of U.S. patent application Ser. No. 11/822,319 under 35 U.S.C. § 120, filed on Jul. 5, 2007, in the United States Patent and Trademark Office and claims priority under 35 U.S.C. § 119 to Korean Patent Application No. 10-2006-0062409, filed on Jul. 4, 2006, in the Korean Intellectual Property Office (KIPO), the entire contents of both incorporated herein by reference.

### BACKGROUND

1. Field

Example embodiments may relate to a doped phase change layer, for example, to a phase change memory device having a doped phase change layer and a method of operation of the phase change memory device.

2. Description of the Related Art

Phase change random access memory (PRAM), flash memory, ferroelectric random access memory (FeRAM), and/or magnetic random access memory (MRAM) may be a non-volatile memory devices. The structural difference between the PRAMs and other non-volatile memories may be a storage node.

A storage node of the PRAM may include a phase change layer. The phase of the phase change layer may change to an amorphous state from a crystalline state at a critical temperature and may change to the crystalline state from the amorphous state at a temperature lower than the critical temperature.

The resistance of the phase change layer while in an amorphous state may be higher than the resistance of the phase change layer while in a crystalline state.

The PRAM may write and/or read data using changeable resistance of the phase change layer based on a state of the phase change layer.

A Ge₂Sb₂Te₅ layer (GST layer) may be used as the phase change layer of the PRAM. A material for the phase change layer of the PRAM may have a lower melting point, a larger resistance difference between a crystalline state and an amorphous state, and/or lower thermal conductivity.

Related art GST layers may have a melting point of more than 600° C. and/or relatively low resistance. If a PRAM uses the related art GST layer as a phase change layer, a large reset current may need to be applied to the GST layer to change the GST layer into an amorphous state.

The reset current of the PRAM may need to be lower than a current supplied by a transistor that may be included in the PRAM. Because the drive current of a transistor may be determined by its size, it may be difficult to reduce the size of the transistor without reducing the reset current. Increase in PRAM integration may be difficult without reducing the reset current.

### SUMMARY

Example embodiments may provide a storage node including a phase change layer with an indium concentration of about 5 at % to about 15 at %.

Example embodiments may provide a storage node including a phase change layer including gallium.

Example embodiments may provide a phase change memory having a doped phase change layer that may have a lowered reset current, a lowered melting point, and/or an increased resistance.

Example embodiments may also provide a method of operating phase change memory.

Example embodiments may provided a phase change memory that may include a storage node having a phase change layer and/or a switching device, wherein the phase change layer includes indium in concentrations ranging from about 5 at % to about 15 at %.

Example embodiments may provided a phase change memory that may include a storage node having a phase change layer and/or a switching device, wherein the phase change layer includes gallium.

The phase change layer may be a GST layer including indium.

The phase change layer may be a GST layer including gallium.

The Ge concentration of the phase change layer may be range from about 10 at % to about 25 at %, the Sb concentration of the phase change layer may range from about 15 at % to about 30 at %, the Te concentration of the phase change layer may range from about 40 at % to about 70 at %.

Example embodiments may provide a method of operating a phase change memory that may include a storage node having a phase change layer and/or a switching device. Example embodiment methods may include writing data by applying a reset current less than about 1 mA to the phase change layer.

The phase change layer may be a GST layer including indium.

The phase change layer may be a GST layer including gallium.

The phase change layer in example embodiments may have a reset current about half of that of a related art GST layer and/or may have increased resistance over related art GST layers.

Example embodiments may provide a method of forming a phase change memory, including forming a first doped region and a second doped region in a semiconductor substrate, forming a gate insulating layer on the semiconductor substrate, the gate insulating layer connected to the first and the second doped regions, forming a gate electrode on the gate insulating layer, forming a interlayer insulating layer over the gate electrode, the first and the second doped regions, and the semiconductor substrate, forming an access hole in the interlayer insulating layer that exposes at least one of the first doped region and the second doped region, filling the access hole with a first conductive plug, forming a lower electrode on the interlayer insulating layer, the lower electrode being electrically connected to the first conductive plug, forming an upper insulating layer over the interlayer insulating layer and the lower electrode, forming a via hole in the upper insulating layer that exposes at least a portion of the lower electrode, filling the via hole with a second conductive plug, forming an Indium-doped GST layer on the upper insulating layer, the indium-doped GST layer being electrically connected to the second conductive plug, and forming an upper electrode on the Indium-doped GST layer.

### BRIEF DESCRIPTION OF THE DRAWINGS

The above and other features and/or advantages of example embodiments will become more apparent by describing in detail the attached drawings in which:

FIG. 1 is a cross-sectional view illustrating an example embodiment phase change memory having a doped phase change layer;

FIG. 2 is graph illustrating characteristics of refractive index versus temperature of a GST layer used in a related art phase change memory and/or a phase change layer used in an example embodiment phase change memory; and

FIG. 3 is a graph illustrating characteristics of resistance versus current of a phase change layer of an example embodiment phase change memory.

### DETAILED DESCRIPTION OF EXAMPLE EMBODIMENTS

Example embodiments will now be described more fully with reference to the accompanying drawings. Example embodiments may, however, be embodied in many different forms and should not be construed as being limited to the example embodiments set forth herein. Rather, these example embodiments are provided so that this disclosure will be thorough, and will fully convey the scope to those skilled in the art. Accordingly, well known processes, well known device structures, and well known techniques are not specifically described to avoid a vague interpretation of the example embodiments. Like reference numerals refer to like elements through the drawings.

It will be understood that when an element or layer is referred to as being “on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there may be no intervening elements or layers present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Thus, a first element, component, region, layer or section discussed below could be termed a second element, component, region, layer or section without departing from the teachings of the example embodiments.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a”, “an” and “the” may be intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-section illustrations that may be schematic illustrations of idealized embodiments (and intermediate structures). As such, variations from the shapes of the illustrations as a result, for example, of manufacturing techniques and/or tolerances, are to be expected. Thus, the example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to limit the example embodiments.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

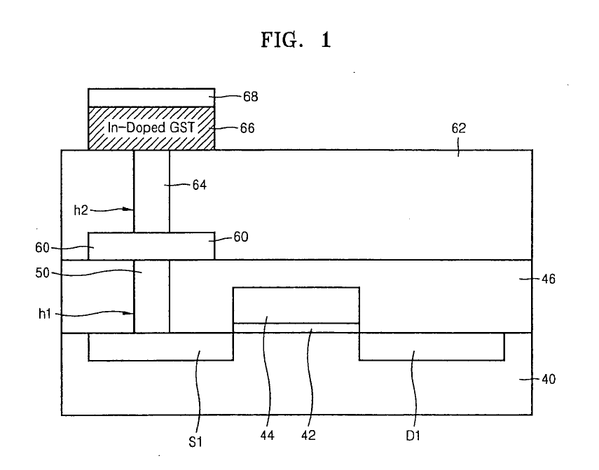

FIG. 1 is a cross-sectional view illustrating an example embodiment phase change memory having an example embodiment doped phase change layer.

As shown in FIG. 1, a first doped region S1 and a second doped region D1 may be separated a desired and/or predetermined distance from each other on a substrate 40. The first and/or second doped regions S1 and D1 may be doped with an n-type dopant, for example. The substrate 40 may be doped with a different type of dopant from the first and second doped regions S1 and D1, for example, a p-type silicon substrate. The first and second doped regions S1 and D1 may be formed in various shapes. One of the first and second doped regions S1 and D1 may be a source region and the other doped region may be a drain region. A gate insulating layer 42 and/or a gate electrode 44 may be stacked on the substrate 40 between the first and second doped regions S1 and D1. The substrate 40, the first and second doped regions S1 and D1, and the gate electrode 44 may form a transistor, for example, a field effect transistor.

A first insulating interlayer 46 may cover the transistor and may be formed on the substrate 40. A contact hole h1 may expose the first doped region S1 and may be formed in the first insulating interlayer 46. The contact hole h1 may be formed to expose the second doped region D1 or the first doped region S1. The contact hole h1 may be filled with a conductive plug 50. A lower electrode 60 may cover an upper surface of the conductive plug 50 and may be formed on the first insulating interlayer 46. The lower electrode 60 may also operate as a pad. The lower electrode 60 may be formed of, for example, TiN, TiAlN, or another suitable substance. A second insulating interlayer 62 may cover the lower electrode 60 and may be formed on the first insulating interlayer 46. The second insulating interlayer 62 may be an insulating layer similar to the first insulating interlayer 46. A second via hole h2 may expose an upper surface of the lower electrode 60 and may be formed in the second insulating interlayer 62. The via hole h2 may be filled with a lower electrode contact layer 64. The lower electrode contact layer 64 may be formed of the same material as the lower electrode 60. A phase change layer 66 may cover an upper surface of the lower electrode contact layer 64 and may be formed on the second insulating interlayer 62. The phase change layer 66 may be a GST layer to which indium and/or gallium is doped and/or added. If the phase change layer 66 is a GST layer doped with indium, the concentration of indium in the phase change layer 66 may range from about 5 at % to about 15 at %. The Ge concentration may range from about 10 at % to about 25 at %, the Sb content may range from about 10 at % to about 30 at %, and/or the Te concentration may range from about 40 at % to about 70 at % in the phase change layer 66. An upper electrode 68 may be formed on the phase change layer 66.

Example embodiment phase change memories may write and/or read data if a reset current smaller than about 1 mA is applied to the phase change layer 66 of the phase change memory.

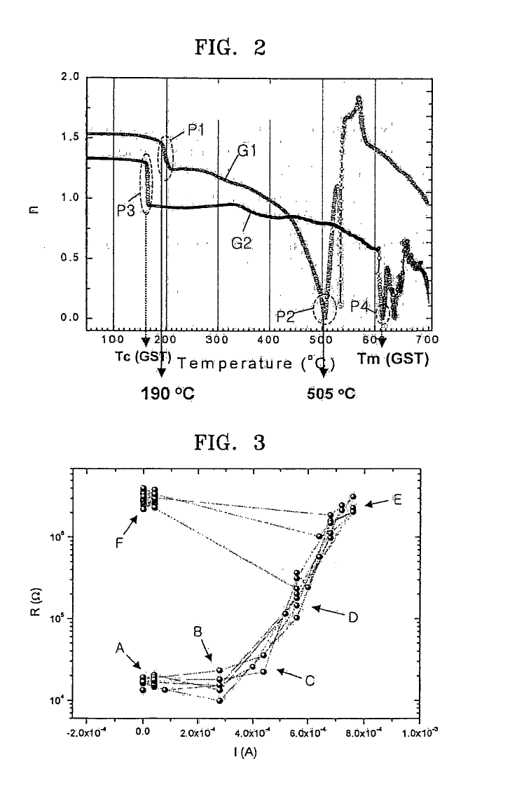

FIG. 2 is graph illustrating characteristic refractive index versus temperature of the phase change layer 66. A first graph G1 shows the refractive index versus temperature of a phase change layer 66 used in an example embodiment phase change memory, and a second graph G2 shows the refractive index versus temperature of a GST layer used in a related art phase change memory.

As shown in the first graph G1, the refractive index may be drop at a first point P1 and continue to drop to a second point P2. However, the refractive index may increase at the second point P2. The first point P1 may appear due to a transformation of the phase change layer 66 from an amorphous state into a crystalline state. The second point P2 may appear due to a transformation of a portion of the phase change layer 66 into an amorphous state, for example, due to melting of a portion of the phase change layer 66. The first point P1 may appear at a temperature of about 190° C. and the second point P2 may appear at a temperature of about 505° C.

As shown in the second graph G2, the refractive index may drop at a third point P3, and the refractive index, which may gradually drop after the third point P3 may increase at a fourth point P4. The cause of the third point P3 may be the same as the first point P1 of the first graph G1, and the cause of the fourth point P4 may be the same reason as the second point P2 of the first graph G1.

If the first and second graphs G1 and G2 are compared, the temperature (about 190° C.) where the first point P1 of the first graph G1 appears may be higher than the temperature Tc(GST) (about 160° C.) where the third point P3 of the second graph G2 appears. The temperature (about 505° C.) where the second point P2 of the first graph G1 may be lower than the temperature Tm(GST) (about 610° C.) where the fourth point P4 of the second graph G2 may appear.

Because the melting point (about 505° C.) of the phase change layer 66 of the example embodiment phase change memory may be lower than the melting point (about 600° C.) of the conventional GST layer, the example embodiment phase change memory may have a lower reset current than related art memory. Example embodiment phase change memory may have improved retention characteristics compared to a related art GST layer because the crystallization temperature (about 190° C.) of the phase change layer 66 of an example embodiment phase change memory may be higher than the crystallization temperature (about 160° C.) of a related art GST layer.

FIG. 3 is a graph illustrating characteristic resistance versus current of the phase change layer 66, in which indium content may be about 10.4 at %, Ge content may be about 17.3 at %, Sb content may be about 20.1 at %, and Te content may be about 52.2 at %, of an example embodiment phase change memory.

In FIG. 3, A may be a state when the phase change layer 66 may be in a crystalline state, and B, C, D, and/or E may be a changing process of resistances if a current is applied to the phase change layer 66 while in a crystalline state.

As shown in FIG. 3, if the state of the phase change layer 66 changes from C state to D state, the resistance of the phase change layer 66 may increase. The increase in the resistance may indicate that the crystalline state of the phase change layer 66 may be changing into an amorphous state. The increase may indicate that an amorphous region may be formed in the crystalline state of the phase change layer 66.

The D state of the phase change layer 66 may appear if the current applied to the phase change layer 66 is about 0.6 mA. The current at which the state of the phase change layer 66 turns into the D state, for example, a reset current, may be less than about 0.6 mA, but, for convenience is illustrated as about 0.6 mA. A reset current of about 0.6 mA of the phase change layer 66 may be about half of the reset current (about 1.2 mA) of the conventional memory that uses the GST layer as the phase change layer. The state F may illustrate the phase change layer 66 in the amorphous state.

As shown in FIG. 3, the phase change layer 66 may maintain a stable amorphous state if the resistance is measured by applying a current greater than the reset current. If a current lower than the reset current, but higher than the set current, is applied to the phase change layer 66 in an amorphous state, the phase change layer 66 may change into a crystalline state, for example, into a state that may have no amorphous region, which is not shown in FIG. 3 for simplicity.

While example embodiments have been particularly shown and described, it will be understood by those of ordinary skill in the art that various changes in form and details may be made therein without departing from the spirit and scope as defined by the following claims.

What is claimed is:

1. A method of operating a phase change memory, comprising:
providing a phase change layer with an indium concentration of about 5 at % to about 15 at %; and
writing data by applying a reset current less than about 1 mA to the phase change layer.

2. The method of claim 1, wherein the phase change layer is a GST layer.

3. The method of claim 2, wherein a Ge concentration of the phase change layer is about 10 at % to about 25 at %.

4. The method of claim 2, wherein a Sb concentration of the phase change layer is about 15 at % to about 30 at %.

5. The method of claim 2, wherein a Te concentration of the phase change layer is about 40 at % to about 70 at %.

6. The method of claim 3, wherein a Sb concentration of the phase change layer is about 15 at % to about 30 at %.
